(19) United States
(12) Patent Application Publication
(10) Pub. No.: US 2022/0198109 A1
(43) Pub. Date: Jun. 23, 2022

(54) BOOLEAN METHODS FOR ENGINEERING CHANGE ORDER (ECO) PATCH IDENTIFICATION

(71) Applicant: Synopsys, Inc., Mountain View, CA (US)

(72) Inventors: Luca AMARU, Santa Clara, CA (US); Maheshwar CHANDRASEKAR, Santa Clara, CA (US); Demosthenes ANASTASAKIS, Portland, OR (US); Makarand PATIL, Portland, OR (US)

(21) Appl. No.: 17/558,952

(22) Filed: Dec. 22, 2021

Related U.S. Application Data
(60) Provisional application No. 63/130,342, filed on Dec. 23, 2020.

(51) Int. Cl. G06F 30/327

(52) U.S. Cl. CPC G06F 30/327

(57) ABSTRACT

A netlist is updated based on an engineering change order (ECO) circuit network by determining primary cuts of a first network of a netlist and secondary cuts of the ECO circuit network. The primary cuts are at least a portion of the first network, and include one or more logic elements and an output node. The secondary cuts are a least a portion of the ECO circuit network, and include one or more logic elements and an output node. Further, matching cuts are determined from the primary cuts and the secondary cuts. The matching cuts include a first cut of the primary cuts and a second cut of the secondary cuts. A downward frontier of the ECO circuit network is determined from the matching cuts, and the netlist is updated based on the downward frontier.

### RELATED APPLICATION

This application claims the benefit of U.S. provisional patent application Ser. No. 63/130,342, filed Dec. 23, 2020, which is hereby incorporated herein by reference.

### TECHNICAL FIELD

The present disclosure relates generally an electronic design automation (EDA) system. In particular, the present disclosure relates to a system and method for identifying a patch for an engineering change order (ECO).

### BACKGROUND

In engineering change order (ECO) patch identification, an important step is to find a frontier cut between an original netlist and an ECO netlist (i.e., a netlist after ECO has been performed). A frontier cut includes a vector of signal (nets) pairs associated between an original netlist and an ECO netlist. A frontier cut can define a valid boundary for the patch for the ECO problem. A frontier cut may define a valid boundary for a smallest patch for the ECO problem. “Pushing the frontier” generally involves trying to identify the pairs of nets closest to the actual ECO, which may minimize the patch size. A cut refers to the concept of cut enumeration and cut computation in synthesis/verification.

### SUMMARY

In one example, a method includes determining primary cuts of a first network of a netlist and secondary cuts of an engineering change order (ECO) circuit network. The primary cuts are at least a portion of the first network, and include one or more logic elements and an output at a top level of the first network. The secondary cuts are a least a portion of the ECO circuit network, and include one or more logic elements and an output at a top level of the ECO circuit network. The method further includes determining matching cuts from the primary cuts and the secondary cuts. The matching cuts include a first cut of the primary cuts and a second cut of the secondary cuts. Further, the method includes determining a downward frontier of the ECO circuit network from the matching cuts, and updating the netlist based on the downward frontier.

In one example, a system includes a memory storing instructions, and a processor. The processor is coupled with the memory to execute the instructions. The instructions when executed cause the processor to determine determining primary cuts of a first network of a netlist and secondary cuts of an ECO circuit network. The primary cuts are at least a portion of the first network, and include one or more logic elements and an output at a top level of the first network. The secondary cuts are a least a portion of the ECO circuit network, and include one or more logic elements and an output at a top level of the ECO circuit network. Further, when executed the instructions cause the processor to determine matching cuts from the primary cuts and the secondary cuts. The matching cuts include one of the primary cuts and one of the secondary cuts. The instructions when executed further cause the processor to determine a downward frontier of the ECO circuit network from the matching cuts, and update the netlist based on the downward frontier.

In one example, a non-transitory computer readable medium comprising stored instructions, which when executed by a processor, cause the processor to determine primary cuts of a first network of a netlist and secondary cuts of an ECO circuit network based on a size parameter corresponding to a number of input nodes. The primary cuts include at least one logic element and an output at a top level of the first network, and the secondary cuts include at least one logic element and an output at a top level of the ECO circuit network. The processor is further caused to determine matching cuts from the primary cuts and the secondary cuts. The matching cuts include first cut of the primary cuts and a second cut of the secondary cuts. Further, processor is caused to increase a volume of the second cut to determine a downward frontier of the ECO circuit network, and update the netlist based on the downward frontier. The volume of the second cut corresponds to a number of gates of the second cut.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates a schematic block diagram of a circuit design system, according to one or embodiments of the disclosure.

FIG. 2 illustrates a flowchart of a method for determining an engineering change order (ECO) patch, according to one or embodiments of the disclosure.

FIG. 3 illustrates a flowchart of a method for patching a netlist, according to one or embodiments of the disclosure.

FIG. 4 illustrates example circuit networks, according to one or embodiments of the disclosure.

FIG. 5 illustrates an example downward frontier of a circuit network, according to one or embodiments of the disclosure.

FIG. 6 illustrates a table of example Input Negation, Input Permutation, and Output Negation equivalences, according to one or embodiments of the disclosure.

FIG. 7 illustrates a table of example Input Negation, Input Permutation, and Output Negation equivalences, according to one or embodiments of the disclosure.

FIG. 8 illustrates a flowchart of a method for determining an ECO patch, according to one or embodiments of the disclosure.

FIG. 9 illustrates a flowchart of a method for determining an ECO patch, according to one or embodiments of the disclosure.

FIG. 10 illustrates example circuit networks, according to one or embodiments of the disclosure.

FIG. 11 depicts a flowchart of various processes used during the design and manufacture of an integrated circuit in accordance with some embodiments of the present disclosure.

FIG. 12 depicts a diagram of an example computer system in which embodiments of the present disclosure may operate.

### DETAILED DESCRIPTION

Aspects of the present disclosure relate to a Boolean method for generating engineering change order (ECO) patch identification.

A functional ECO is used for logic rectification at late design stages of a circuit. In one or more examples, a minimal logic difference is identified between the original netlist and the revised netlist, which is called a patch. A scalable Boolean method is described herein and is based on a matching process that identifies a compact patch. The described Boolean method is capable of finding a high quality frontier with scalable runtime. Further, the Boolean method can implement an efficient use of Boolean reasoning techniques tailored to the ECO problem.

In one or more embodiments, in performing ECO patch identification, one or more frontier cuts between an original one or more netlists and the ECO netlists are found. Frontier cuts include a vector of signal (nets) pairs associated between an original netlist and an ECO netlist. A frontier defines a valid boundary for the patch for a corresponding ECO problem. In one example, a frontier defines a valid boundary for the smallest patch for a corresponding ECO problem. In one or more examples, “pushing the frontier” refers to identifying the pairs of nets closest to an ECO that minimize the patch size.

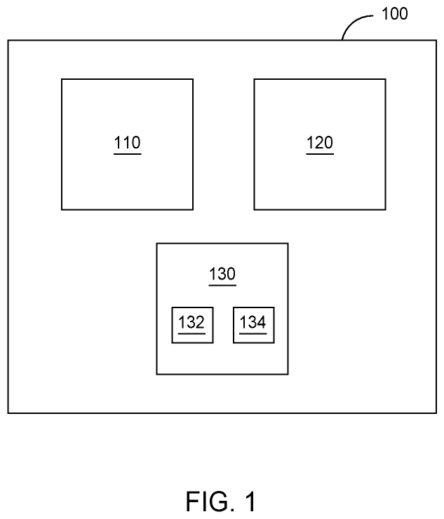

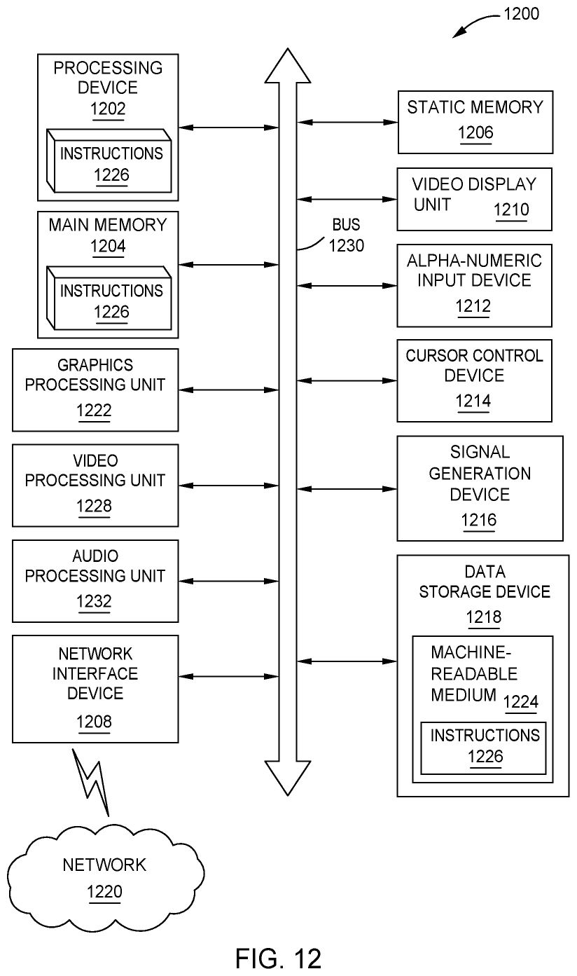

FIG. 1 illustrates circuit design system 100, according to one or more examples. The circuit design system 100 may be an electronic design automation (EDA) system, or other design systems or tools. The circuit design system 100 is used during the design and/or verification of a circuit design. The circuit design system 100 includes one or more processors (e.g., the processing device 1202 of FIG. 12) that execute instructions (e.g., the instructions 1226 of FIG. 12) stored in a memory (e.g., the main memory 1204 and/or the machine-readable medium 1224 of FIG. 12) to generate a circuit design and/or verify the circuit design. In one or more examples, the circuit design system 100 receives an engineering change order (ECO) circuit network, determines an ECO patch from the ECO circuit network, and updates a netlist of a circuit design based on the ECO patch. In one example, an ECO circuit network includes two or more interconnected circuit components. An ECO circuit network includes one or more nodes (e.g., signal nodes or input nodes) and one or more circuit components. The circuit components are interconnected via the signal nodes.

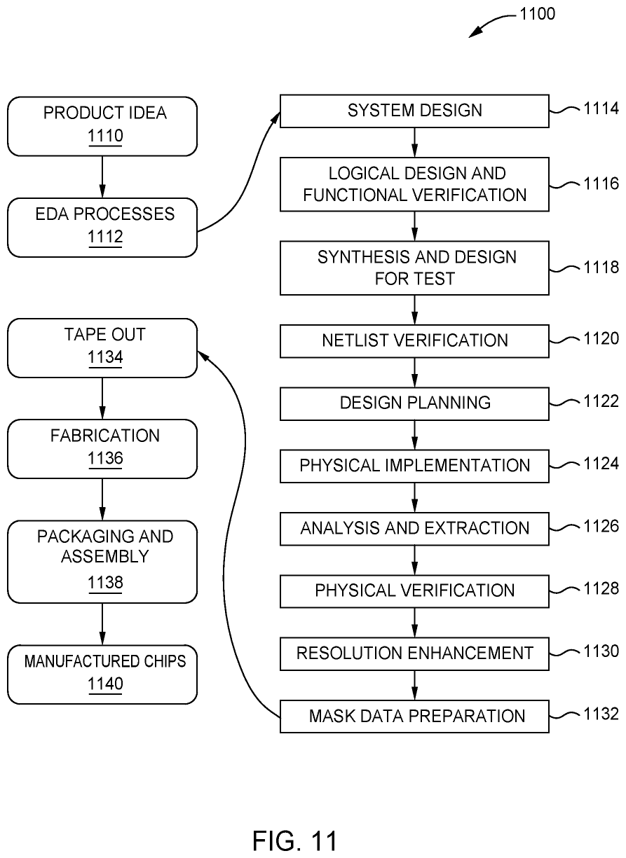

The circuit design system 100 includes a cut engine 110, a patch engine 120, and a memory 130. The cut engine 110 includes one or more processors (e.g., the processing device 1202 of FIG. 12) that execute instructions (e.g., the instructions 1226 of FIG. 12) stored in a memory (e.g., the memory 130, the main memory 1204 of FIG. 11, and/or the machine-readable medium 1224 of FIG. 11). The cut engine 110 obtains a netlist (e.g., the netlist 132) and an ECO circuit network (e.g., the ECO circuit network 134), and identifies a patch of the ECO circuit network, which is used to update the netlist. In one example, a processor of the circuit design system 100 executes instructions associated with the cut engine 110 to perform the functions of the cut engine 110.

The cut engine 110 obtains the netlist 132 from the memory 130 and the ECO circuit network 134 from the memory 130. The cut engine 110 identifies a network of the netlist 132 to be updated by the ECO circuit network 134 and an ECO patch of the ECO circuit network 134.

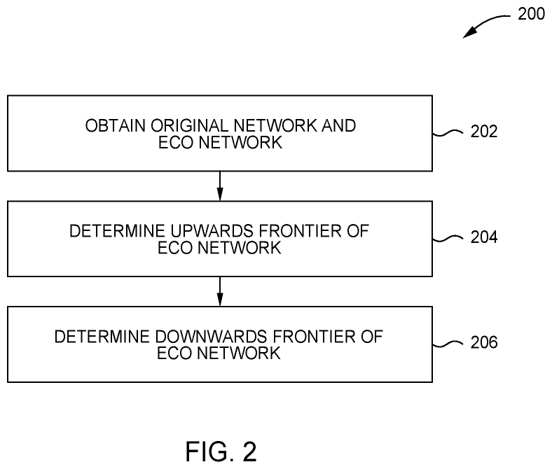

FIG. 2 is a flowchart of a method 200 for identifying a patch of the ECO circuit network 134 to update the netlist 132, according to one or more examples. The method 200 is executed by the cut engine 110.

At 202 of the method 200, the netlist 132 and the ECO circuit network 134 are obtained. For example, the cut engine 110 obtains the netlist 132 and the ECO circuit network 134 from the memory 130. The netlist 132 may have already undergone synthesis and validation. In one example, netlist synthesis includes converting a circuit design from a register transfer level (RTL) to a gate level netlist including nets, sequential cells, and/or combinational cells. Further, netlist validation (e.g., verification) includes checking the netlist for compliance with timing constraints and for correspondence with hardware description language (‘HDL’) code.

At 204 of the method 200, an upwards frontier of the ECO circuit network 134 is determined. The upwards frontier can be determined by matching primary inputs of the ECO circuit network 134 to primary inputs of a network of the netlist 132. In one example, a bottom-up analysis is applied to the ECO circuit network 134 to determine the upwards frontier. For example, the ECO circuit network 134 is analyzed starting from the primary inputs and moving towards the primary output or outputs, identifying the logic between the primary inputs and primary output or outputs. In one example, satisfiability (SAT) sweeping satisfiability (SAT) is used to identify the upwards frontier. SAT sweeping is a method for simplifying the ECO circuit network 134 by systematically merging graph vertices from the primary inputs to the output or outputs using a combination of structural hashing, simulation, and SAT queries.

A primary output is the output port at a top level of the design the ECO circuit network 134 or the netlist 132. A primary input is an input port at the top level of the design of the ECO circuit network 134 or the netlist 132.

At 206 of the method 200, a downwards frontier of the ECO circuit network 134 is determined. The downwards frontier is determined based on a top-down analysis (e.g., from primary outputs moving towards primary inputs). The upwards and downwards frontiers are used for minimization of the ECO path. For example, the upwards and downwards frontiers are used to identify the logic of the ECO circuit network that makes up the ECO patch. In one example, the upwards and downwards frontiers are used to identify the input and output nodes and corresponding logic between the input and output nodes to identify the ECO patch. An ECO patch is identified as the logic of the ECO circuit network between the upwards frontier and the downwards frontier. The ECO patch is stored in the memory 130. The method for identifying the ECO patch is described in greater detail in the following.

With further reference to FIG. 1, the patch engine 120 obtains the netlist 132 and the ECO patch from the memory 130. The patch engine 120 updates the netlist 132 based on the ECO patch. The updated netlist is stored in the memory 130. The patch engine 120 includes one or more processors (e.g., the processing device 1202 of FIG. 12) that execute instructions (e.g., the instructions 1226 of FIG. 12) stored in a memory (e.g., the memory 130, the main memory 1204 of FIG. 11, and/or the machine-readable medium 1224 of FIG. 11). The patch engine 120 updates the netlist 132 based on the ECO patch and stores the updated netlist in the memory 130. In one example, a processor of the circuit design system 100 executes instructions associated with the patch engine 120 to perform the functions of the patch engine 120.

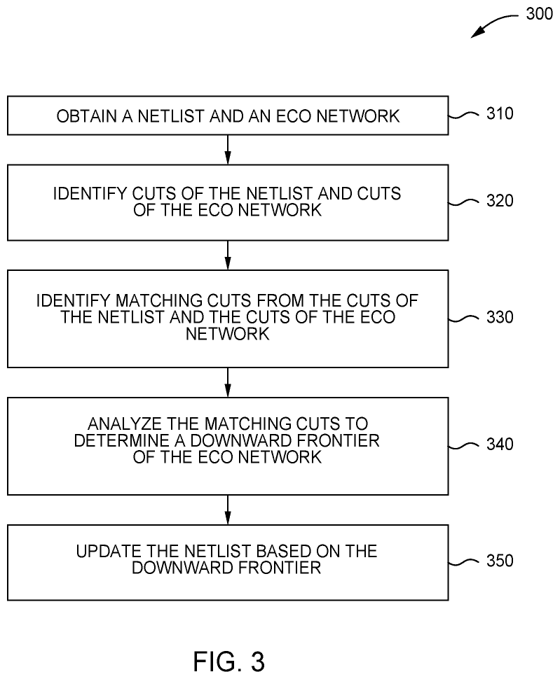

FIG. 3 illustrates a flowchart of a method 300 for updating a netlist with an ECO patch, according to one or more examples. In one example, the method 300 is executed as instructions by one or more processors of the circuit design system 100. Further, in one or more examples, the method 300 may be performed as part of netlist verification 1120 of FIG. 11. At 310, a netlist and ECO circuit network are obtained by a cut identification engine. In one example, the cut engine 110 obtains the netlist 132 and the ECO circuit network 134 from the memory 130. At 320, cuts of the netlist and cuts of the ECO circuit network are determined. For example, the cut engine 110 determines cuts of a network within the netlist 132 and cuts of the ECO circuit network 134. Cuts refer to cut enumeration and/or cut computation in synthesis/verification.

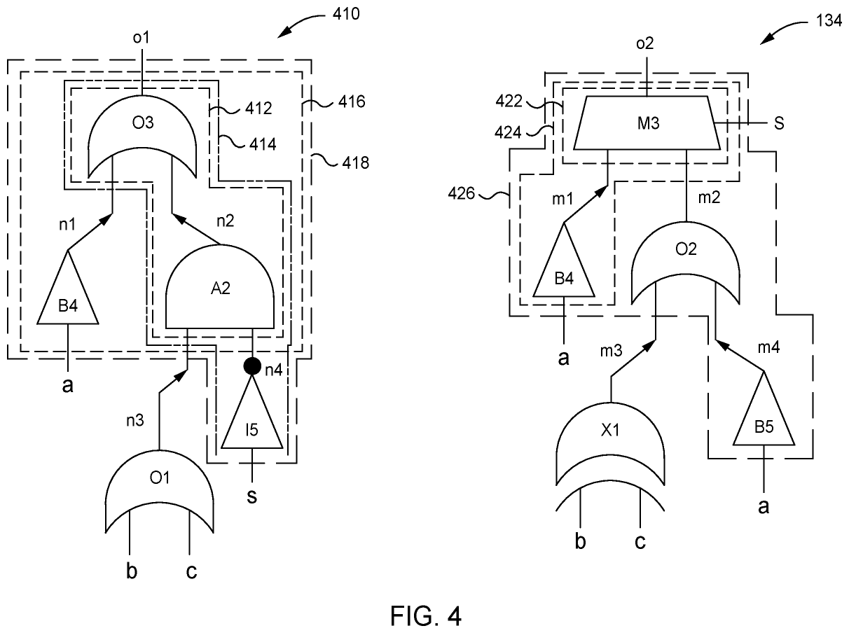

FIG. 4 illustrates a network 410 of the netlist 132 and the ECO circuit network 134. The network 410 includes a primary output of and primary inputs a, b, c, and s. The ECO circuit network 134 includes a primary output o2 and primary inputs a, b, c, and s. As can be seen from FIG. 4, the logic of the network 410 differs from the logic of the ECO circuit network 134. Cuts of the network 410 and the ECO circuit network 134 are identified to determine a largest downward frontier of the ECO circuit network 134 and the network 410 that are similar. By determining the largest downward frontier ensures that the minimal amount of change is made to the netlist 132.

In one example, a cut of a gate N includes one or more logic gates (or gates) of a network such that each path from a primary input gate N passes through at least one leaf. Gate N is a root of cut C. Leaves are the primary inputs to a cut. Further, a cut size corresponds to the number of leaves within the cut. For example, with reference to FIG. 4, a cut 418 of cut size 3 includes gates O3, B4, A2, and I5, as the primary inputs (leaves) are input a, input n3, and input s. In one example, a trivial cut includes a single leaf. Further, a volume of a cut is the total number of gates encountered on all paths between gate N and the leaves of the cut.

Further, a frontier is a cut (e.g., a frontier cut) that starts from a primary output of a network such that the portion of the circuit of the network is functionally equivalent to a corresponding portion of another network.

In one example, the cuts are identified based on a size K. The size k corresponds to a number of input nodes of each cut. In one example, size K has a value between 1 and 16. In other examples, size K has a value greater than 16. The present system may set the value of size K at a particular value, or receive a value (e.g., from a user). In the example of FIG. 4, the value of size K is set to 3. With reference to FIG. 4, the cut engine 110 identifies cuts of the network 410 starting from the primary output o1 based on the cut size of 3. As illustrated in FIG. 4, cuts (e.g., primary cuts) 412, 414, 416, and 418 are identified within the network 410. The cut 412 has a primary output of o1 and inputs of n1, n3, and n4. The cut 414 has a primary output of o1 and inputs of n1, n3, and s. The cut 416 has a primary output of o1 and inputs of a, n3, and n4. The cut 418 has a primary output of o1 and inputs of a, n1, and s. Further, the cuts (secondary cuts) 422, 424, and 426 are identified within the ECO circuit network 134. The primary output of is the primary output for all of the cuts 412, 414, 416, and 418. The inputs to the cut 412 is n1 and n2, the inputs to cut 414 are a and n2, the inputs to the cut 416 are a, n3, and n4, and the inputs to the cut 418 are a, n3, and S. The primary output o2 is the primary output for the cuts 422, 424, and 426. The inputs to the cut 422 are m1, m2, and s. The inputs to cut 424 are a, m2, and s. The inputs to the cut 426 are a, m3, and s. Each of the cuts 412-418 and 422-426 has three inputs (leaves) and one output.

At 330 of FIG. 3, matching cuts from the cuts of the netlist and the cuts of ECO circuit network are identified. For example, the cut engine 110 identifies matching cuts from the cuts 412-418 and the cuts 422-426. In one example, identifying the matching cuts includes removing cuts from the identified cuts. The removed cuts may include trivial cuts. Trivial cuts may include cuts that differ from another cut of the same set by a logic gate, but have the same functionality or differ by an inverted input. In one example, the logic gate has one input and one output. In one or more examples, the logic gate is a buffer or inverting buffer, among others. For example, in the set of cuts 412-418, the cut 418 is determined to differ from the cut 416 by an inverting buffer I5. As the cut 416 the input n4 is the inverse of the input s of the cut 418. Accordingly, the cut 418 may be removed from the set of cuts 412-418, such that the cuts 412, 414, and 416 remain. Further, the cut 424 is determined to differ from the cuts 422 by the buffer B4. Accordingly, the cut 424 may be removed from the respective set of cuts. Further, as the cut 426 is determined to be a possible trivial cut as the cut 426 has multiple buffers B4 and B5. Accordingly, the cut 426 is determined to have the same functionality as a cut including inputs a, m3, m4, and s. As the cut 426 has the same fame functionality as another cut within the ECO circuit network 134, the cut 426 is determined to be a trivial cut. Accordingly, the cuts 424 and 426 may be removed from the corresponding set of cuts 422-426, such that the cut 422 remains.

Identifying the matching cuts further includes identifying a pair of cuts from the network 410 and the ECO circuit network 134 that have a largest volume. In one example, a pair of cuts having the largest volume is the pair of cuts having the largest number of gates within the corresponding network. In another example, a pair of cuts having the largest is the pair of cuts that travel the deepest within the corresponding network (e.g., traverses the largest number of gates). In one or more examples, a pair of cuts having the largest value is the pair of cuts having the largest number of gates and that travels the deepest within the corresponding network. With reference to FIG. 4, the cut 416 and the cut 422 are determined to have the largest volume from the respective sets of cuts. In one or more examples, to determine if cuts are matching, a truth table for each cut is determined. The truth tables of the cut 416 and the cut 422 are compared to determine if the cuts 416 and 422 are matching (e.g., have a matching functionality). The truth tables are then compared. If the truth tables are determined to be matching, then the cuts are identified to be matching.

In one example, based on a determination by the cut engine 110 that the truth tables do not match, functional permutations of the pair of matching cuts are obtained. Functional permutation can involve attempting different assignments to associate sets of signals. For example, given (a,b) and (x,y), two possible permutations exist: a->x, b->y and b->x, a->y. The cut engine 110 determines whether any obtained valid functional permutation of the cut of the original network of the pair of matching candidate cuts is equivalent to any obtained valid functional permutation of the cut 422 of the ECO circuit network 134. Many functions are equivalent under permutation or inversion of inputs and inversion of outputs. For example, f=a′ b, g=b a are equivalent under inversion of input a. In one example, f=a′ b, h=b+a′ are equivalent under inversion of output h and permutation of a,b. In one or more examples, f=a′ b, k=ab′ are equivalent under permutation of inputs a, b. The equivalence under all three operations (Input Negation, Input Permutation, and Output Negation) is commonly called NPN-equivalence. In one example, for large K sizes, logic characteristics may be used to reduce the possible permutations that are analyzed. Large K sizes may be 6 or more. In other examples, a large K size is two or more. The logic characteristics may include unateness property and variable symmetry that can be used for filter permutation. An unateness property corresponds to a Boolean function that has monotonic properties. Variable symmetry is a symmetric function where the value is the same regardless of the order of the corresponding arguments.

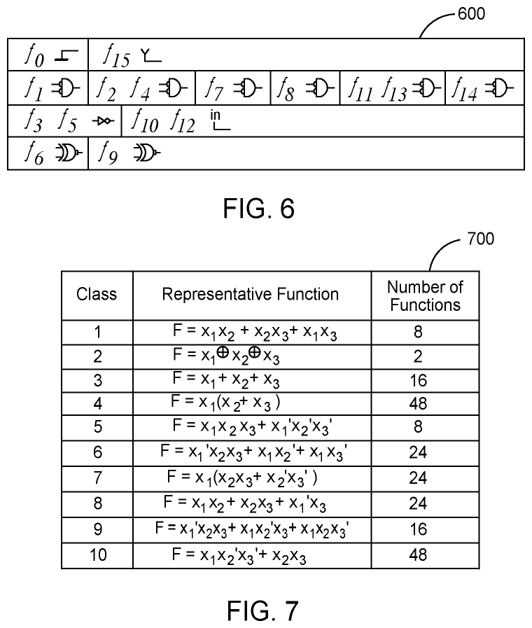

In one or more examples, 2-input functions can be classified into 4 NPN classes as illustrated in the table 600 of FIG. 6. The functions in each row of the table 600 are equivalent to each other. As illustrated in the table 600, the function ƒ₆ is equivalent to the function ƒ₉. Table 700 of FIG. 7 illustrates NPN classes for 3-input functions. As illustrated in the table 700, the 3-input functions have 10 NPN classes. In one or more examples, efficient packages for NPN computation and matching in synthesis can be used, such as up to 5 variables, and partially for larger functions. Representations of the functional permutations can be stored in the memory 130 as a look-up table (LUT), a database, or other storage element, or can be generated on the fly during the analysis by the cut engine 110.

Based on a determination of valid functional permutations being equivalent, the leaves are added to the downward frontier. Based on a determination that no obtained valid functional permutations are equivalent, other logic gates are analyzed for possible inclusion in the downward frontier.

At 340 of the method 300, the matching cuts are analyzed to determine a downward frontier of the ECO circuit network. For example, the cut engine 110 analyzes the cuts 416 and 422 to determine the downward frontier of the ECO circuit network 134. Determining the downward frontier includes pushing the cut 422 downward in the network to determine if additional leaves, and logic, can be included in the cut. Pushing the cut 422 includes identifying leaves connected to the cut 422 that can be included without changing the functionality between the cut 422 and the cut 416. As is described above, the downward frontier may be determined based on determining an updated truth table for each leaf outside the cut 422. For example, to determine whether or not the buffer logic B4 and input a are to be included in the downward frontier, a truth table is generated based on the buffer logic B4, input a, multiplexer logic M3, input M2 and input s. The truth table is compared to the truth table of cut 416 of network 410. Based on a determination that the truth tables match, the leaf of buffer logic B4 and the input a are added to the downward frontier. This process is repeated for each leaf extending downward (e.g., away from the primary output o2) to determine which leaves to include and which to not include.

For example, pushing down from input m1 identifies input a and buffer logic B4. As input m1 is a buffered version of input a, input a and buffer logic B4 is included in the cut 422. Pushing down from input m2 identifies an OR gate O2 and inputs m3 and m4. The input m2 is equivalent to performing an OR function on the inputs m3 and m4 (e.g., via the OR gate O2). The OR gate O2, and inputs m3 and m4 do not change the functionality (e.g., truth table) of the cut 422. Accordingly, the input m3 and m4, and the OR gate O2 may be included in the cut 422. Buffer logic B5 and input a are identified by pushing down from input m4. Input m4 is a buffered version of input a and does change the functionality of the cut 422. Accordingly, input a and buffer logic B5 is included in the cut 422. Pushing down from node m3 identifies XOR gate X1 and inputs b and c. However, as the XOR gate X1 alters functionality of the cut 422 and differs in functionality from the OR gate O1 in the network 410, the XOR gate X1 and the input b and c are not included in the cut 422.

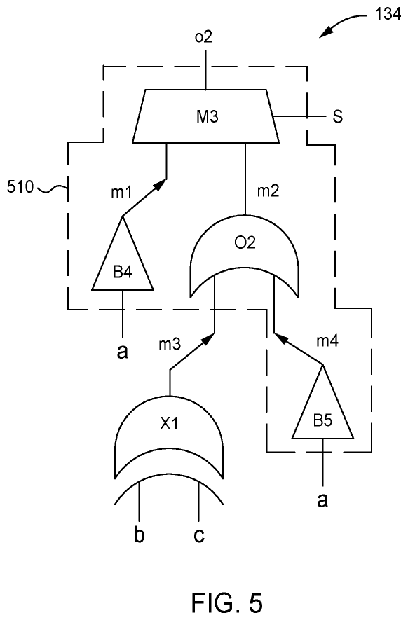

FIG. 5 illustrates the ECO circuit network 134 with the downward frontier 510. The downward frontier 510 is the cut 422 pushed downward to further include input a, input m3, buffer logic B4, buffer logic B5, and OR gate O2.

At 350 of the method 300, the netlist is updated based on the downward frontier. For example, the netlist 132 is updated based on the downward frontier 510 of FIG. 5. The patch engine 120 updates the netlist 132. For example, the patch engine 120 determine an ECO patch from the ECO circuit network 134 and the downward frontier 510. The ECO patch corresponds to the logic of the ECO circuit network 134 excluded from the downward frontier 510. For example, with reference to FIG. 5, the ECO patch includes the logic XOR gate X1 and inputs b and c.

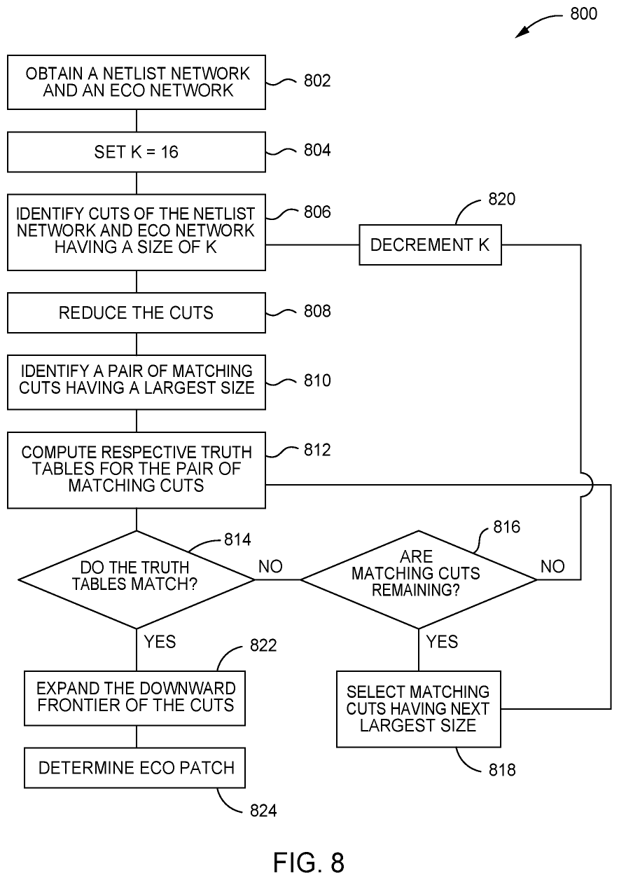

FIG. 8 illustrates a flowchart of a method 800 for determining an ECO patch, according to one or more examples. The method 800 is executed by instructions by one or more processors of the circuit design system 100 of FIG. 1. At 802, a netlist network and an ECO circuit network are obtained. For example, with reference to FIG. 1, the cut engine 110 obtains the netlist network from the netlist 132 stored within the memory 130 and the ECO patch from the memory 130.

At 804, K, the size value of the cuts, is set to a particular value, e.g., 16. In other examples, the K may be set to a value greater than or less than 16. With reference to FIG. 1, the cut engine 110 sets the value of K to 16. At 806, cuts of the netlist network and cuts of the ECO circuit network having a size K are determined. For example, the cut engine 110 identifies cuts of the netlist network and cuts of the ECO circuit network having a size K. The size K corresponds to a number of leaves (inputs) of a cut.

In one example, the cut engine 110 identifies the primary outputs of the netlist network and ECO circuit network and identified and added to a frontier stack (e.g., inserted into a first in, first out logical list). The frontier stack stores the primary outputs such that the primary outputs may be obtained and used later in the process of identifying an ECO patch. The primary outputs may be sorted based on a first in first out basis. In other examples, the primary outputs are sorted based on other orders. The primary outputs of the networks can be ordered to correspond to each other and pushed to the initial frontier stack in that order.

The cut engine 110 identifies the cuts of the netlist network and the ECO circuit network starting from the primary outputs of the netlist network and the ECO circuit network. For example, with reference to FIG. 4, the cuts of the network 410 are identified starting from the primary output of and the cuts of the ECO circuit network 134 are identified starting from the primary output o2. The cuts can be identified using a cut enumeration process based on the value of K. In the example of FIG. 4, K has a value of 3, and the cuts 412-418 are identified in the network 410 and the cuts 422-426 are identified in the ECO circuit network 134.

In one or more examples, for K values of 6 or more, the leaves of the cuts may be grouped based on characteristics to reduce the amount of processing that is used to analyze the cuts. In one or more examples, the gates within a cut are simulated to determine the number of times the output of the gates switch values. The leaves of the cuts may be grouped based on the number of times that the corresponding logic switches values.

At 808, the obtained cuts are reduced, if possible. The cut engine 110 may use a number of different considerations to reduce the number of cuts. Reducing the number of cuts reduces the number of cuts that are analyzed to find a matching cut, decreasing the processing time to determine the ECO patch.

A first consideration is to remove cuts where the difference(s) with another cut of the same network is trivial, such as cuts with similar functionality (e.g., with the presence of one or more buffers). Another consideration is to remove cuts that are not legal, e.g., a boundary of the respective cut crosses or overlaps with the corresponding upwards frontier.

At 810, a pair of matching cuts having a largest volume are identified. The cut engine 110 identifies the matching cuts having the largest volume. Matching cuts can be paired based on functional signatures, including considering unateness, binateness, and symmetry information. Symmetry information corresponds to where logic of the cuts have the same function regardless of the order. For example, a cut having a functional signature having a non-inverted signal and the inverted version of that signal (e.g., being binate) cannot match a cut having a functional signature that has a non-inverted signal but not the inverted version of that signal (e.g., being unate), and hence, those cuts are not paired (but can be excluded) as matching cuts. If the number of matching cuts is too large, e.g., so large that the analysis would be expected to not converge on a solution or would take too long to converge, an exception can be initiated, and the method 800 can be halted.

The cut engine 110 identifies a pair of matching cuts having a largest size. For example, a size of a cut corresponds to how much logic each cut includes. Cuts of the netlist network and the ECO circuit network 134 having the largest size are identified by analyzing the cuts to identify the size of each cut, and matching the cuts having a largest size. In one example, matching cuts that have a largest size can increase the uniqueness of each cut, which (non-intuitively) can increase efficiency of the analysis. The pair of matching cuts includes a cut of the netlist network and a cut of the ECO circuit network 134.

At 812, the respective truth tables for the pair of matching cuts are computed. The cut engine 110 computes a truth table for the pair of matching cuts. Based on the truth tables matching, the downward frontier of the cuts is expanded at 822. The cut engine 110 expands the downward frontier of the pair of matching cuts to include additional leaves, increasing the size of the downward frontier. In one example, the cut engine 110 identifies leaves of the cut of the ECO circuit network 134 and determines if the leaves are to be included in the final downward frontier based on an updated truth table generated based on the inclusion of the leaves. If the inclusion of a leaf does not change the truth table of the cut, the leaf is included. If the inclusion of a leaf does change the truth table of the cut of the ECO circuit network, the leaf is not included.

At 824, an ECO patch is determined. The patch engine 120 determines the ECO patch from the downward frontier determined at 822. The patch engine 120 compares the downward frontier to the ECO circuit network 134 and generates the ECO patch based on the logic differences between the ECO circuit network 134 and the downward frontier. For example, with reference to FIG. 5, the ECO patch includes the XOR logic gate X1, as the XOR logic gate X1 is not included in the downward frontier identified by the downward frontier 510.

If the truth tables do not match, functional permutations of the pair of matching candidate cuts are obtained as described above with regard to FIG. 3. If obtained valid functional permutations are equivalent, the leaves of the pair of matching candidate cuts are added to the downward frontier. If no obtained valid functional permutations are equivalent, a determination is made whether any other matching cuts (e.g., not already analyzed) are remaining at 816. If 816 determines that there are other matching cuts, the next matching cuts having a largest next size is selected at 818 and the method loops back to 812. If 816 determines that there are no matching cuts remaining, K is decremented at 820, and the method loops back to 806.

In one or more examples, 816 and 818 are omitted. In such examples, based on the determination that the truth tables do not match at 814, K is decremented at 820, and the method 800 loops back to 806.

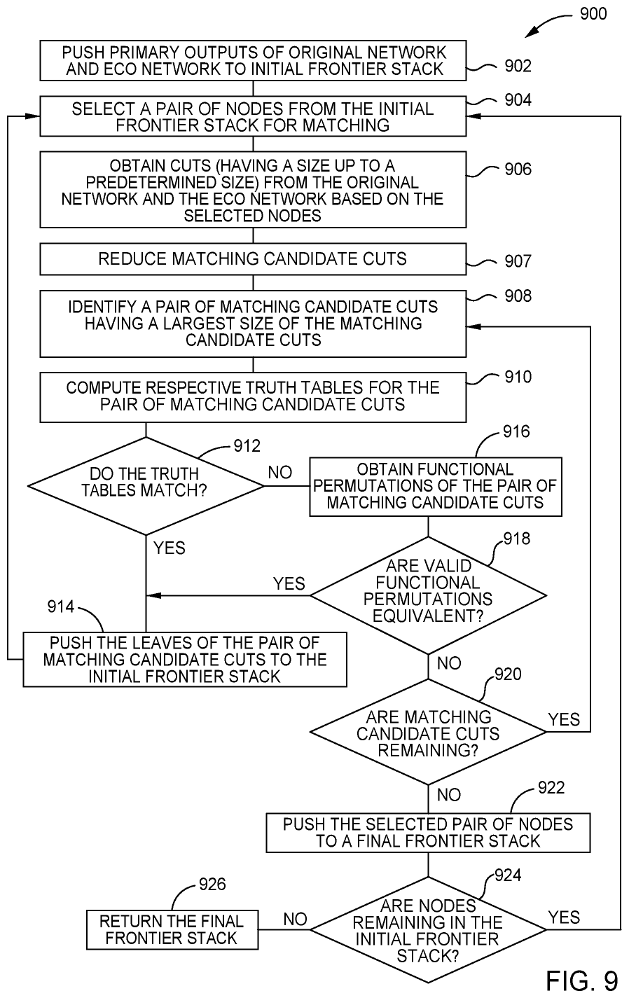

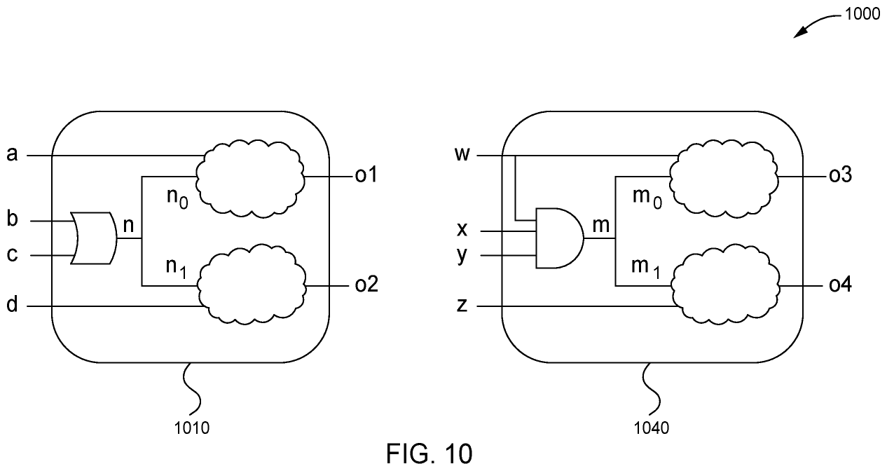

FIG. 9 is a flowchart of a method 900 for determining a downwards frontier, according to some examples. At 902, primary outputs of the original network (e.g., a network of the netlist 132) and primary outputs of the ECO circuit network (e.g., ECO circuit network 134) are pushed to an initial frontier stack (e.g., inserted into a first in, first out logical list). The primary outputs of the networks can be ordered to correspond to each other and pushed to the initial frontier stack in that order. At 904, a pair of nodes from the initial frontier stack are selected (e.g., retrieved from a first in, first out logical list) for matching. One node of the pair is a node of the original network (e.g., a network of the netlist 132), and the other node of the pair is a node of the ECO circuit network (e.g., ECO circuit network 134). At 906, one or more cuts of the original network are obtained based on the node of the pair that is the node of the original network, and one or more cuts of the ECO circuit network are obtained based on the node of the pair that is the node of the ECO circuit network. The sizes of the cuts are based on a predetermined size.

At 907, matching candidate cuts of the obtained cuts are reduced, if possible. A number of different considerations can be implemented to reduce the number of cuts for matching candidate cuts. A first consideration is to remove cuts where the difference(s) with another cut of the same network is trivial, such as the presence of one or more buffers. Another consideration is to remove cuts that are not legal, e.g., a boundary of the respective cut crosses or overlaps with the previously determined upwards frontier. Matching candidate cuts are paired based on size. For example, a cut of the original network having a size of seven cannot match a cut of the ECO circuit network having a size of three, and hence, those cuts are not paired (but can be excluded) as matching candidate cuts. For example, a cut having a functional signature having a non-inverted signal and the inverted version of that signal (e.g., being binate) cannot match a cut having a functional signature that has a non-inverted signal but not the inverted version of that signal (e.g., being unate), and hence, those cuts are not paired (but can be excluded) as matching candidate cuts. If the number of candidate matching cuts is too large, e.g., so large that the analysis would be expected to not converge on a solution or would take too long to converge, an exception can be thrown, and the method can be halted.

At 908, a pair of matching candidate cuts having a largest size are identified from the matching candidate cuts of 3907. Analyzing the matching candidate cuts that have a largest size can increase the uniqueness of each cut, which can increase efficiency of the analysis. The pair of matching candidate cuts includes a cut of the original network based on the selected node of the original network and a cut of the ECO circuit network based on the selected node of the ECO circuit network. At 910, the respective truth tables for the pair of matching candidate cuts are computed. At 912, a determination is made whether the truth tables match. If the truth tables match, the leaves of the pair of matching candidate cuts are pushed to the initial frontier stack at 914. The nodes selected from the initial frontier stack at 904 of that iteration can then be invalidated or discarded, including cuts obtained at 906 and reduced at 907 based on those nodes. Pushing the leaves to the initial frontier stack conceptually pushes the downward frontier further downward. After 914, operation loops back to 904 to select another pair of nodes from the initial frontier stack.

If the truth tables do not match, functional permutations of the pair of matching candidate cuts are obtained at 916. Functional permutation can involve attempting different assignments to associate sets of signals. For example, given (a,b) and (x,y), two possible permutations exist: a->x, b->y and b->x, a->y. At 918, a determination is made whether any obtained valid functional permutation of the cut of the original network of the pair of matching candidate cuts is equivalent to any obtained valid functional permutation of the cut of the ECO circuit network of the pair of matching candidate cuts. Many functions are equivalent under permutation or inversion of inputs and inversion of outputs. For example, f=a′ b, g=b a are equivalent under inversion of input a. For example, f=a′ b, h=b+a′ are equivalent under inversion of output h and permutation of a,b. For example, f=a′ b, k=ab′ are equivalent under permutation of inputs a, b. The equivalence under all three operations may be referred to as NPN-equivalence. Two input functions can be classified into 4 NPN classes as illustrated in the table 600 of FIG. 6. Three input function have 10 NPN classes as illustrated in FIG. 7. In one example, efficient packages for NPN computation and matching in synthesis can be used, such as up to 5 variables exhaustively, and partially for larger functions. Representations of the functional permutations can be stored in a look-up table (LUT), a database, or other storage element, or can be generated on the fly during the analysis.

If obtained valid functional permutations are equivalent, the leaves of the pair of matching candidate cuts are pushed to the initial frontier stack at 914. The nodes selected from the initial frontier stack at 904 of that iteration can then be invalidated or discarded, including cuts obtained at 906 and reduced at 907 based on those nodes.

If no obtained valid functional permutations are equivalent, a determination is made whether any other matching candidate cuts (e.g., not already analyzed) are remaining at 920. If 918 determines that there are no valid functional permutations that are equivalent, conceptually, the pair of matching candidates do not match, and the downward frontier cannot be pushed further downward based on that pair of matching candidates.

If other matching candidate cuts are remaining based on the determination at 920, operation loops back to 908 to iteratively analyze another pair of matching candidate cuts (e.g., having a same size or the next largest size relative to the size of the pair analyzed in the preceding iteration). If there are no other matching candidate cuts, the pair of nodes selected at 904 of that iteration are pushed to a final frontier stack at 922. If there are no other matching candidate cuts without finding a matching pair of cuts, conceptually, the frontier cannot be pushed further downward based on the nodes selected at 904 of that iteration, and those nodes form at least part of the downwards frontier as indicated by the final frontier stack.

At 924, a determination is made whether any nodes remain in the initial frontier stack. If nodes remain in the initial frontier stack, operation loops back to 904. If no nodes remain in the initial frontier stack, the final frontier stack is returned at 926. The nodes in the final frontier stack form the downward frontier of the ECO circuit network.

FIG. 10 illustrates example netlist network 1010 and ECO circuit network 1040. The primary outputs of and o2 of the netlist network 1010 are based on inputs n0, n1, a, and d. Signals n0 and n1 are equal to signal n. The primary outputs o3 and o4 of the ECO circuit network 1040 are based on inputs m0, m1, w, and z. Inputs m0 and m1 are equal to input m. The cut engine 110 determines the downward frontier of the ECO circuit network 1040 as described above with regard to FIG. 3 and FIG. 8. However, as the downward frontier is expanded (e.g., pushed) to include additional leaves, the boundaries of the downward frontier starting from the primary outputs o1 and o3 is expanded to match inputs a and w, inputs b and x, and inputs c and y. Further, the downward frontier starting from the primary outputs o2 and o4 is expanded to match inputs n and m, and signals d and z. However, a conflict is formed in the netlist network 1010 at the input n (specifically at input n0) for the primary output o1, as the input n is attempted to be patched with x or y of the ECO circuit network 1040. Further, a conflict is formed in the netlist network 1010 as, for the primary output o2, the signal n (specifically at signal n1) is attempted to be patched with an AND function of the signals w, x, and y. As both the inputs n0 and n1 are the input n, a conflict arises as when patched, inputs n0 and n1 are based on different functions. In one example, to mitigate the conflict the downward frontier of the ECO circuit network 1040 is stopped at input m, and input n of the netlist network 1010. In another example, to mitigate the conflict, the downward frontier of the ECO circuit network 1040 is expanded to go beyond the input m, and the input n of the netlist network 1010. The downward frontier is later accepted or rejected based on correctness with respect to impacted rectification points of the downward frontier. A downward frontier is accepted if no new output pair fails an equivalence between the netlist network and the ECO circuit network. If a new output fails an equivalence between the netlist network and the ECO circuit network, the downward frontier is rejected and the next deepest downward frontier is selected and a determination as to whether reject that downward frontier is made. The process is repeated until a downward frontier is accepted.

FIG. 11 illustrates an example set of processes 1100 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 1110 with information supplied by a designer, information which is transformed to create an article of manufacture that uses a set of EDA processes 1112. When the design is finalized, the design is taped-out 1134, which is when artwork (e.g., geometric patterns) for the integrated circuit is sent to a fabrication facility to manufacture the mask set, which is then used to manufacture the integrated circuit. After tape-out, a semiconductor die is fabricated 1136 and packaging and assembly processes 1138 are performed to produce the finished integrated circuit 1140.

Specifications for a circuit or electronic structure may range from low-level transistor material layouts to high-level description languages. A high-level of representation may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding tools of that layer (e.g., a formal verification tool). A design process may use a sequence depicted in FIG. 11. The processes described by be enabled by EDA products (or tools).

During system design 1114, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 1116, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 1118, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 1120, the netlist is checked for compliance with timing constraints and for correspondence with the HDL code. During design planning 1122, an overall floor plan for the integrated circuit is constructed and analyzed for timing and top-level routing.

During layout or physical implementation 1124, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 1126, the circuit function is verified at the layout level, which permits refinement of the layout design. During physical verification 1128, the layout design is checked to ensure that manufacturing constraints are correct, such as DRC constraints, electrical constraints, lithographic constraints, and that circuitry function matches the HDL design specification. During resolution enhancement 1130, the geometry of the layout is transformed to improve how the circuit design is manufactured.

During tape-out, data is created to be used (after lithographic enhancements are applied if appropriate) for production of lithography masks. During mask data preparation 1232, the ‘tape-out’ data is used to produce lithography masks that are used to produce finished integrated circuits.

A storage subsystem of a computer system (such as computer system 1200 of FIG. 12) may be used to store the programs and data structures that are used by some or all of the EDA products described herein, and products used for development of cells for the library and for physical and logical design that use the library.

FIG. 12 illustrates an example machine of a computer system 1200 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1200 includes a processing device 1202, a main memory 1204 (e.g., read-only memory (ROM), flash memory, dynamic random access memory (DRAM) such as synchronous DRAM (SDRAM), a static memory 1206 (e.g., flash memory, static random access memory (SRAM), etc.), and a data storage device 1218, which communicate with each other via a bus 1230.

Processing device 1202 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1202 may also be one or more special-purpose processing devices such as an application specific integrated circuit (ASIC), a field programmable gate array (FPGA), a digital signal processor (DSP), network processor, or the like. The processing device 1202 may be configured to execute instructions 1226 for performing the operations and steps described herein.

The computer system 1200 may further include a network interface device 1208 to communicate over the network 1220. The computer system 1200 also may include a video display unit 1210 (e.g., a liquid crystal display (LCD) or a cathode ray tube (CRT)), an alphanumeric input device 1212 (e.g., a keyboard), a cursor control device 1214 (e.g., a mouse), a graphics processing unit 1222, a signal generation device 1216 (e.g., a speaker), graphics processing unit 1222, video processing unit 1228, and audio processing unit 1232.

The data storage device 1218 may include a machine-readable storage medium 1224 (also known as a non-transitory computer-readable medium) on which is stored one or more sets of instructions 1226 or software embodying any one or more of the methodologies or functions described herein. The instructions 1226 may also reside, completely or at least partially, within the main memory 1204 and/or within the processing device 1202 during execution thereof by the computer system 1200, the main memory 1204 and the processing device 1202 also constituting machine-readable storage media.

In some implementations, the instructions 1226 include instructions to implement functionality corresponding to the present disclosure. While the machine-readable storage medium 1224 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1202 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method comprising:
determining primary cuts of a first network of a netlist and secondary cuts of an engineering change order (ECO) circuit network, wherein the primary cuts are at least a portion of the first network, and include one or more logic elements of the first network, and an output at a top level of the first network, and the secondary cuts are a least a portion of the ECO circuit network, and include one or more logic elements of the ECO circuit network, and an output at a top level of the ECO circuit network;
determining matching cuts from the primary cuts and the secondary cuts, the matching cuts include a first cut of the primary cuts and a second cut of the secondary cuts;
determining, by a processor, a downward frontier of the ECO circuit network from the matching cuts; and
updating the netlist based on the downward frontier.

2. The method of claim 1, wherein determining the matching cuts comprises reducing a number of at least one of the primary cuts and the secondary cuts.

3. The method of claim 1, wherein the primary cuts and the secondary cuts are identified based on a size parameter corresponding to a number of nodes, and wherein the size parameter is decremented based on a determination that a match between the primary cuts and the secondary cuts does not exist.

4. The method of claim 3, wherein determining the matching cuts comprises matching the first one of the primary cuts with the first one of the secondary cuts, wherein the first one of the primary cuts and the first one of the secondary cuts have a same size parameter.

5. The method of claim 1, wherein determining the downward frontier of the ECO circuit network comprises identifying an input of the ECO circuit network to include in the downward frontier.

6. The method of claim 5, wherein the identifying the input of the ECO circuit network comprises determining a functionality of the second cut is unchanged by the input.

7. The method of claim 5, wherein identifying the input of the ECO circuit network to include in the downward frontier generates an updated downward frontier, and wherein the netlist is updated based on the updated downward frontier based on a comparison of the downward frontier to the first cut.

8. The method of claim 1, wherein determining the matching cuts from the primary cuts and the secondary cuts comprises determining a first truth table for the first cut and a second truth table for the second cut, and the matching cuts are determined based on the first truth table and the second truth table.

9. The method of claim 8, wherein, based on a determination that the first truth table does not match the second truth table, functional permutations of one or more of the first cut and the second cut are determined, and the matching cuts are determined based on the functional permutations.

10. The method of claim 1, wherein updating the netlist based on the downward frontier comprises updating the netlist with the ECO circuit network excluding the downward frontier.

11. A system comprising:
a memory storing instructions; and
a processor, coupled with the memory to execute the instructions, the instructions when executed cause the processor to:
determine primary cuts of a first network of a netlist and secondary cuts of an Engineering Change Order (ECO) circuit network, wherein the primary cuts are at least a portion of the first network, and include one or more logic elements of the first network, and an output at a top level of the first network, and the secondary cuts are a least a portion of the ECO circuit network, and include one or more logic elements of the ECO circuit network, and an output at a top level of the ECO circuit network;
determine matching cuts from the primary cuts and the secondary cuts, the matching cuts include one of the primary cuts and one of the secondary cuts;
determine a downward frontier of the ECO circuit network from the matching cuts; and
update the netlist based on the downward frontier.

12. The system of claim 11, wherein determining the matching cuts comprises reducing a number of at least one of the primary cuts and the secondary cuts.

13. The system of claim 11, wherein the primary cuts and the secondary cuts are identified based on a size parameter corresponding to a number of input nodes, and wherein the size parameter is decremented based on a determination that a match between the primary cuts and the secondary cuts does not exist.

14. The system of claim 11, wherein determining the downward frontier of the ECO circuit network comprises determining an input of the ECO circuit network to include in the downward frontier.

15. The system of claim 11, wherein determining the matching cuts from the primary cuts and the secondary cuts comprises determining a first truth table for the first cut and a second truth table for the second cut, and the matching cuts are determined based on the first truth table and the second truth table.

16. The system of claim 15, wherein, based on a determination that the first truth table does not match the second truth table, functional permutations of one or more of the first cut and the second cut are determined, and the matching cuts are determined based on the functional permutations.

17. A non-transitory computer readable medium comprising stored instructions, which when executed by a processor, cause the processor to:
determine primary cuts of a first network of a netlist and secondary cuts of an Engineering Change Order (ECO) circuit network based on a size parameter corresponding to a number of input nodes, wherein the primary cuts include at least one logic element of the first network, and an output at a top level of the first network, and the secondary cuts include at least one logic element of the ECO circuit network, and an output at a top level of the ECO circuit network;
determine matching cuts from the primary cuts and the secondary cuts, the matching cuts include first cut of the primary cuts and a second cut of the secondary cuts;
increase a volume of the second cut to determine a downward frontier of the ECO circuit network, wherein the volume of the second cut corresponds to a number of gates of the second cut; and
update the netlist based on the downward frontier.

18. The non-transitory computer readable medium of claim 17, wherein the size parameter is decremented based on a determination that a match between the primary cuts and the secondary cuts does not exist.

19. The non-transitory computer readable medium of claim 17, wherein increasing the volume of the second cut includes identifying an input node of the ECO circuit network to include in the second cut, and determining that functionality of the second cut is unchanged by the input node.

20. The non-transitory computer readable medium of claim 17, wherein determining the matching cuts from the primary cuts and the secondary cuts comprises determining a first truth table for the first cut and a second truth table for the second cut, and the matching cuts are determined based on the first truth table and the second truth table.
